(19) United States
(12) Patent Application Publication
(10) Pub. No.: US 2004/0016919 A1
(43) Pub. Date: Jan. 29, 2004

(54) Solid-state image sensor

(75) Inventors: Hiroshi Daiku, Kawasaki (JP); Shigeru Nishio, Kawasaki (JP); Asao Kokubo, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 10/611,994

(22) Filed: Jul. 3, 2003

(30) Foreign Application Priority Data
Jul. 25, 2002 (JP) 2002-216848
Oct. 30, 2002 (JP) 2002-316280

(51) Int. Cl. H01L 29/06; H01L 31/0328

(52) U.S. Cl. 257/14; 257/18

(57) ABSTRACT

A solid-state image sensor able to adjust sensitivity in a wide range without causing flicker or stripes, even when the illumination source is a fluorescent lamp, has been disclosed. The solid-state image sensor comprises: plural pixels and; a gain variable amplifier that amplifies signals sequentially read from the plural pixels at a fixed cycle time and the amplification factor of which can be varied, and the storage time of the pixel can be set to an arbitrary value, wherein the sensor comprises: a brightness/illumination flicker detection section; and a control section that varies the storage time step by step to one of plural flicker-less times in accordance with the detected brightness and the illumination flicker as well as varying the amplification factor of the amplifier in accordance with the detected brightness and the storage time.

This application is based upon and claims the benefit of priority from the prior Japanese Patent Application Nos. 2002-216848 and 2002-316280, respectively filed in July 25 and Oct. 30, 2001, the entire contents of which are incorporated herein by reference.

### BACKGROUND OF THE INVENTION

The present invention relates to a solid-state image sensor. More particularly, the present invention relates to a solid-state image sensor that reduces flicker noise, due to a fluorescent lamp, during indoor shooting.

Image sensors include an image pickup tube and a solid-state image pickup device (solid-state image sensor), and most of them are a storage type except for special ones used to observe high-speed phenomena. A storage type image sensor stores signal charges corresponding to an incident light image in pixels, which are read sequentially in a scanning manner and become an output signal current. Each pixel stores the signal charges during the period of scanning cycle.

Recently, a solid-state image sensor has been used as a built-in device in many products such as digital cameras and portable terminals. The solid-state image sensors include a CCD type solid-state image pickup device (CCD type image sensor) composed of a charge transfer type image sensor and a CMOS type solid-state image pickup device (CMOS type image sensor), the image sensor of which is composed of CMOS transistors. The CMOS type image sensor can be manufactured with the same technology as the MOSFET manufacturing process and is expected to replace CCD image sensors because it can be driven by a single power source, its power consumption is small, and various signal processing circuits can be mounted on a single chip. The present invention is applicable to any solid-state image sensor, that is, both to a CCD type image sensor and a CMOS type image sensor. A CMOS type image sensor is particularly described here as an example, but the present invention is not limited to this.

The CMOS image sensor has plural pixel areas arranged in a matrix which are connected to plural vertical selection lines and horizontal selection lines and. In each pixel area, photoelectric conversion devices such as a photodiode are formed. The light incident on the light receiving surface of each photoelectric conversion device is photoelectrically converted and charges are stored in the device. The stored charges are amplified by a source follower amplifier or the like provided within each pixel and are read as image data for each pixel at a fixed timing. Plural pieces of image data connected to the fixed horizontal selection lines are output at one time in response to the row selection signal from the vertical scanning shift register, and then are output sequentially to the external system side from the horizontal shift register in response to a column selection signal.

As the solid-state image sensor used in digital cameras and portable terminals cannot adjust the amount of incident light by means of an optical aperture or the like, it is required to be equipped with an automatic gain control function with which to automatically adjust an output in accordance with the brightness (illuminance) when shooting using the solid-state image sensor. In one of the most general methods of automatic gain control, the amplifier at the output section of a solid-state image sensor is replaced with a gain-variable amplifier and a constant output level can be always obtained by varying the amplification factor (gain) of the amplifier in accordance with the highest level or average level of an image.

In another method of automatic gain control, the storage time is varied. As described above, each pixel of a solid-state image sensor stores charges from the time it reads a signal until it reads a signal next. This storage time relates to the sensitivity, that is, the shorter the storage time, the less charge is stored, resulting in degradation of sensitivity. Recently, the solid-state image sensor has been equipped with a function with which to reset charges stored in each pixel in a unit of a row, therefore, the storage time can be shortened arbitrarily. The function to vary the storage time is utilized in the automatic gain control.

FIG. 1 and FIG. 2 are diagrams illustrating the automatic gain control in a conventional CMOS image sensor. FIG. 1 shows adjustment of the number of integral lines corresponding to the storage time and FIG. 2 shows adjustment of gain. In FIG. 1 and FIG. 2, the lower graph shows an enlarged part of the upper graph in the 0 to 2000 range of the value of brightness. It is assumed here that the CMOS image sensor has 512 rows and each pixel data is read at a 30 Hz read cycle. Therefore, the storage time is 1/30 sec. at most and the number of integral lines is 512 in this case. If the storage time is shortened the number of integral lines becomes less than 512 accordingly.

The value of brightness is data of the detected amount of light incident on the CMOS image sensor and expressed in, for example, 14-bit data, that is, the value ranges from 0 to 1616384. The value 0 means the maximum brightest and as the value increases the brightness becomes lower. As shown in FIG. 1 and FIG. 2, while the value of brightness varies from 0 to 1000, the number of integral lines is increased to increase the sensitivity. When the value of brightness varies and exceeds 1000, the gain is increased with the number of integral lines being fixed to the maximum value.

In the case of indoor shooting, a fluorescent lamp is frequently used for illumination, but it is known that shooting under the illumination of a fluorescent lamp causes flicker noise in images due to the flicker of the fluorescent lamp. The amount of emitted light of a fluorescent lamp varies at a frequency twice that of the power supply frequency. Therefore, in an area where the power supply frequency is 50 Hz, the amount of emitted light of a fluorescent lamp varies at 100 Hz, and in an area where the power supply frequency is 60 Hz, it varies at 120 Hz. The relationship between the light emission frequency of a fluorescent lamp and the storage time of a solid-state image sensor brings about a problem.

FIG. 3 is a diagram illustrating the occurrence of flicker noise, and (a) shows a case where the light emission frequency is 100 Hz and (b) shows a case where the light emission frequency is 120 Hz. The signal storage of the photodiode of a pixel connected to the x-th horizontal selection line (referred to as the x-th line hereinafter) from the top of the first frame is described below using FIG. 3. Let the signal storage beginning time at the x-th line be 1xb, the signal storage ending time be 1xe, and the signal storage time (integral time) be ts. If the total of the vertical scanning period and the vertical blanking period from the first horizontal selection line to the last one is assumed to be one frame period T, one frame period T=1/30 sec, for example, therefore, the frame frequency f=30 Hz.

As shown in FIG. 3 (b), when the light emission period of a fluorescent lamp is 1/120 sec, an integer multiple (quadruple) of the light emission period of the fluorescent lamp coincides with one frame period of the CMOS image sensor. Therefore, the timing of the signal storage beginning time 1xb and the signal storage ending time 1xe at the x-th line is the same in the n-th frame and the next (n+1)-th frame with respect to the light emission period of the fluorescent lamp. As a result, shooting under the illumination of a fluorescent lamp whose light emission frequency is 120 Hz causes a constant brightness of an image in each frame.

As shown in FIG. 3 (a), on the other hand, when the light emission period of a fluorescent lamp is 1/100 sec, an integer multiple of the light emission period of the fluorescent lamp does not coincide with one frame period of the CMOS image sensor, which is approximately 3.3 times the period in this example. Therefore, unless the signal storage time ts is adjusted to the light emission period of the fluorescent lamp, the timing of the signal storage beginning time 1xb and the signal storage ending time 1xe are not the same in the n-th frame and the (n+1)-th frame with respect to the light emission period of the fluorescent lamp. As a result, shooting under the illumination of a fluorescent lamp whose light emission frequency is 100 Hz causes the brightness of an image to differ from frame to frame, resulting in the occurrence of flicker.

FIG. 3 shows a problem of a relationship between frames, but in the case of the signal storage of pixels connected to different horizontal lines in the same frame, the timing is not the same with respect to the light emission period of a fluorescent lamp for both the light emission frequencies 100 Hz and 120 Hz. As a result, there occurs difference in brightness in each row in the same frame for both the light emission frequencies 100 Hz and 120 Hz, resulting in occurrence of bright and dark stripes in an image. It is necessary to set the storage time to an integer multiple of the light emission period of a fluorescent lamp in order to avoid the occurrence of flicker and stripes due to shooting under the illumination of a fluorescent lamp.

Conventionally, such a problem is solved by setting the storage time to an integer multiple of the light emission period for 50 Hz and 60 Hz, respectively, when the value of brightness is 1000 or greater, but a problem still persists that flicker and stripes are caused in the 0 to 1000 range of the value of brightness because the storage time is varied in this range. However, in an actual use, as the intensity of illumination is small when indoor shooting is carried out under the illumination of a fluorescent lamp, that is, the value of brightness is 1000 or greater in most cases, the method of sensitivity adjustment as shown in FIG. 1 and FIG. 2 brings no serious problem.

However, there are areas with power supply frequency of 50 Hz and areas of 60 Hz in Japan, and the storage time is set on shipping in accordance with the supposed destination of the product. However, a problem of occurrence of flicker and stripes persists if the power supply frequency is inappropriate.

In order to solve such a problem, the present applicants have disclosed a configuration in Japanese Unexamined Patent Publication (Kokai) No. 2002-330350, in which flicker in the illuminating light is detected from the output signal of the solid-state image sensor, whether the illumination is provided by a fluorescent lamp lit at 50 Hz or 60 Hz, and then the storage time is set to a value in accordance with the light emission period of the fluorescent lamp.

Moreover, Japanese Unexamined Patent Publication (Kokai) No. 10-304249 has disclosed another method for reducing flicker noise.

Recently, the solid-state image sensor, particularly the CMOS image sensor has improved in sensitivity, therefore, the sensitivity adjustment cannot be carried out sufficiently unless the integral time is varied, even for indoor shooting under the illumination of a fluorescent lamp, that is, the illumination in which the light intensity is relatively small.

### SUMMARY OF THE INVENTION

It is an object of the present invention to solve these problems and realize a solid-state image sensor in which sensitivity can be adjusted in a wide range without occurrence of flicker or stripes due to the illumination by a fluorescent lamp.

In order to realize the above-mentioned object, in the solid-state image sensor of the present invention, sensitivity is adjusted using both the storage time and the amplification factor of the amplifier. To this end, the solid-state image sensor of the present invention is characterized in that a gain variable amplifier is used as an amplifier, which amplifies a signal read from a pixel, a brightness/illumination flicker detection section is provided, which detects the brightness and the illumination flicker of an incident light image, and while the storage time is varied, step by step, to one of plural flicker-less times without occurrence of illumination flicker in accordance with the detected brightness and the illumination flicker, the amplification factor of the gain variable amplifier is varied in accordance with the detected brightness and the set value of the storage time.

As sensitivity is adjusted using both the storage time and the amplification factor of the amplifier, the solid-state image sensor of the present invention has a wide adjustable range. The storage time is varied step by step to a flicker-less time without occurrence of flicker for 120 Hz or 100 Hz by detecting illumination flicker in order to prevent flicker or stripes from occurring even if the storage time is varied, and the total sensitivity varies smoothly by using the amplification factor of the amplifier simultaneously as the storage time is varied step by step.

When the illumination flicker has a 100 Hz light emission period, which is the period when a fluorescent lamp is operated at 50 Hz, the storage time is set to n/100 sec (n is 1, 2 or 3), and when the illumination flicker has a 120 Hz light emission period, which is the period when a fluorescent lamp is lit at 60 Hz, the storage time is set to n/120 sec (n is 1, 2, 3 or 4).

The brightness/illumination flicker detection section can be realized by the configuration disclosed in Japanese Unexamined Patent Publication (Kokai) No. 2002-330350, in which the average luminance of a pixel signal is detected in each frame in the fixed average luminance detection area assigned in a frame, the difference in the average luminance between frames is calculated, and whether the illumination flicker is due to a fluorescent lamp operated at 50 Hz or 60 Hz is judged from the difference in the calculated average luminance. However, the present invention is not limited to this, and any detection method can be used as long as it can detect the brightness and the illumination flicker of an incident light image.

### BRIEF DESCRIPTION OF THE DRAWINGS

The features and advantages of the invention will be more clearly understood from the following description taken in conjunction with the accompanying drawings in which:

FIG. 1 is a diagram showing the variation in the number of integral lines in a conventional example of the automatic gain control of a solid-state image sensor;

FIG. 2 is a diagram showing the variation in the gain of the amplifier in a conventional example of the automatic gain control of a solid-state image sensor;

FIG. 3 is a diagram illustrating a problem of flicker due to illumination of a fluorescent lamp;

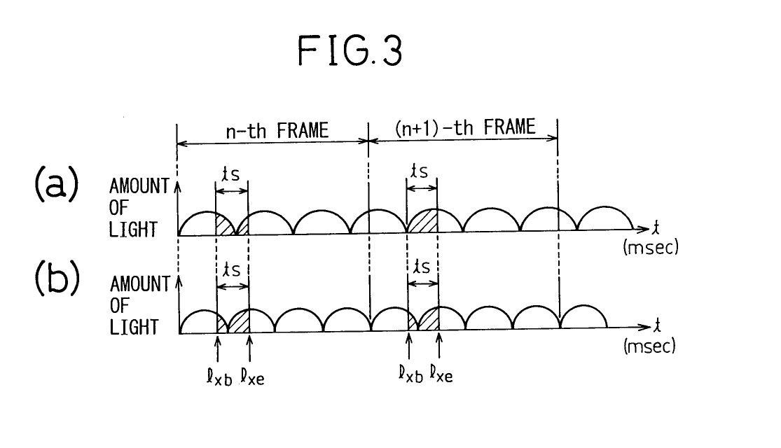

FIG. 4 is a diagram showing the configuration of the CMOS image sensor in the embodiments of the present invention;

FIG. 5 is a diagram showing the variation in the number of integral lines in the automatic gain control of the solid-state image sensor in the embodiments;

FIG. 6 is a diagram showing the variation in the gain of the amplifier in the automatic gain control of the solid-state image sensor in the embodiments;

FIG. 7 is a diagram showing the control values when the power supply frequency is 100 Hz for the automatic gain control of the solid-state image sensor in the embodiments;

FIG. 8 is a diagram showing the control values when the power supply frequency is 120 HZ for the automatic gain control of the solid-state image sensor in the embodiments;

FIG. 9 is a flow chart of the processing for detecting illumination flicker; and

FIG. 10 is a diagram showing the average luminance detection area for the processing for detecting illumination flicker.

### DESCRIPTION OF THE PREFERRED EMBODIMENTS

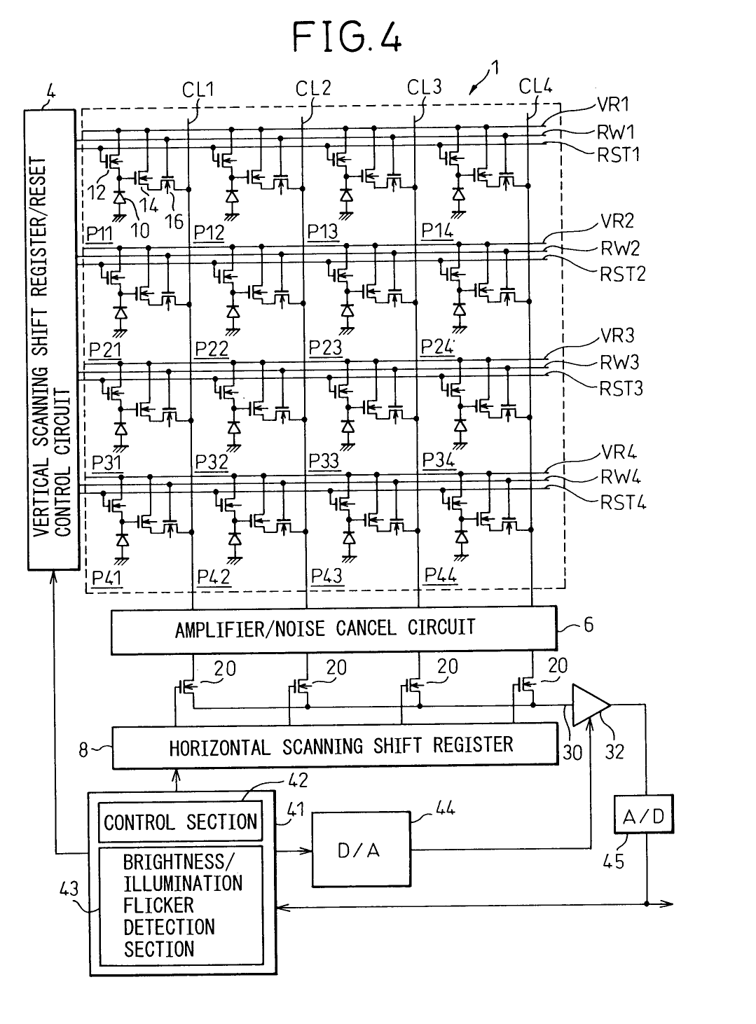

FIG. 4 is a diagram showing the configuration of the CMOS image sensor in the embodiments of the present invention.

FIG. 4 shows a circuit example of 4×4 pixels of a CMOS image sensor 1 that has a pixel array with m rows and n columns. Pixel areas P11 to P44 to be connected to plural vertical selection lines CL1 to CL4 and horizontal selection lines RW1 to RW4 are arranged in matrix. In each of the pixel areas P11 to P44, a photodiode 10 is formed as a photoelectric transfer device. The photoelectric transfer device can be realized by, for example, a photo gate instead of the photodiode 10.

The CMOS image sensor has an APS (Active Pixel Sensor) configuration, in which a source follower amplifier 14, a horizontal selection transistor 16, and the like composed of, for example, MOSFET's (in the present embodiment, N channel MOSFET's are shown for example) arranged, in each pixel area P11 to P44.

The circuit configuration of a pixel area Pmn, where m denotes the row number and n denotes the column number, is described below. The cathode side of the photodiode 10 in the pixel area Pmn is connected to, for example, the source electrode of a reset transistor 12 composed of an N channel MOSFET and the gate electrode of the source follower amplifier 14.

The drain electrode of each reset transistor 12 is connected to a reset voltage supply line VRm to which a reset voltage VR is applied, and the gate electrode is connected to a reset signal line RSTm. The drain electrode of the source follower amplifier 14 is connected to the reset voltage supply line VRm, and the source electrode is connected to, for example, the drain electrode of the horizontal selection transistor 16 composed of an N channel MOSFET. The gate electrode of each horizontal selection transistor 16 is connected to a horizontal selection line RWm to which a selection signal is supplied. The source electrode of each horizontal selection transistor 16 is connected to a vertical selection line CLn.

The reset voltage supply line VRm and the horizontal selection line RWm are connected to a vertical scanning shift register/reset control circuit 4. By means of a shift register, which is not shown here but is provided in the vertical scanning shift register/reset control circuit 4, a selection signal is output sequentially to the horizontal selection line RWm at a fixed timing.

Each vertical selection line CLn is connected to a signal common output line 30 via an amplifier/noise cancel circuit 6 and, for example, a column selection transistor 20 composed of an N channel MOSFET. A column selection signal is input sequentially from a horizontal scanning shift register 8 to the gate electrode of the column selection transistor 20, and by means of the amplifier/noise cancel circuit 6, the image data from which the fixed pattern noise has been removed is output sequentially to the signal common output line 30, then it is transmitted to an external system via an amplifier 32. The amplifier 32 is a gain variable amplifier, the amplification factor (gain) of which can be varied.

Next, the operations of the CMOS image sensor 1 are briefly described below. First, when the reset transistor 12 is turned on by a reset signal RST at a fixed timing, the photodiode 10 is charged to a reset potential VR. Then the photodiode 10 begins to discharge in accordance with the incident light and the potential becomes lower than the reset potential VR. After a fixed time elapses, when a horizontal selection signal RW is output to the horizontal selection line RWm, the horizontal selection signal RW is input to the gate electrode of the horizontal selection transistor 16 connected to the horizontal selection line RWm, and the horizontal selection transistor 16 is turned on. In this way, the output voltage from the source follower amplifier 14 is output to the vertical selection line CLn as the image data in the pixel area Pmn.

The CMOS image sensor in the present invention has a microprocessor 41, a D/A converter 44, and an A/D converter 45, in addition to the above-mentioned configuration. Within the microprocessor 41, there are provided as software a control section 42 that controls the CMOS image sensor 1 and a brightness/illumination flicker detection section 43 that detects the brightness and illumination flicker of the light image incident on the pixel from the output signal, which is the output of the amplifier 32 converted into digital signal in the A/D converter 45. The microprocessor 41 outputs data with which to set a timing (that is, the number of integral lines) for outputting a reset signal to the vertical scanning shift register/reset control circuit 4 according to the detected brightness and illumination flicker, and at the same outputs data with which to set a gain of the amplifier 32 to the D/A converter 44. In accordance with this, the storage time (number of integral lines) is set and the gain of the amplifier 32 is set.

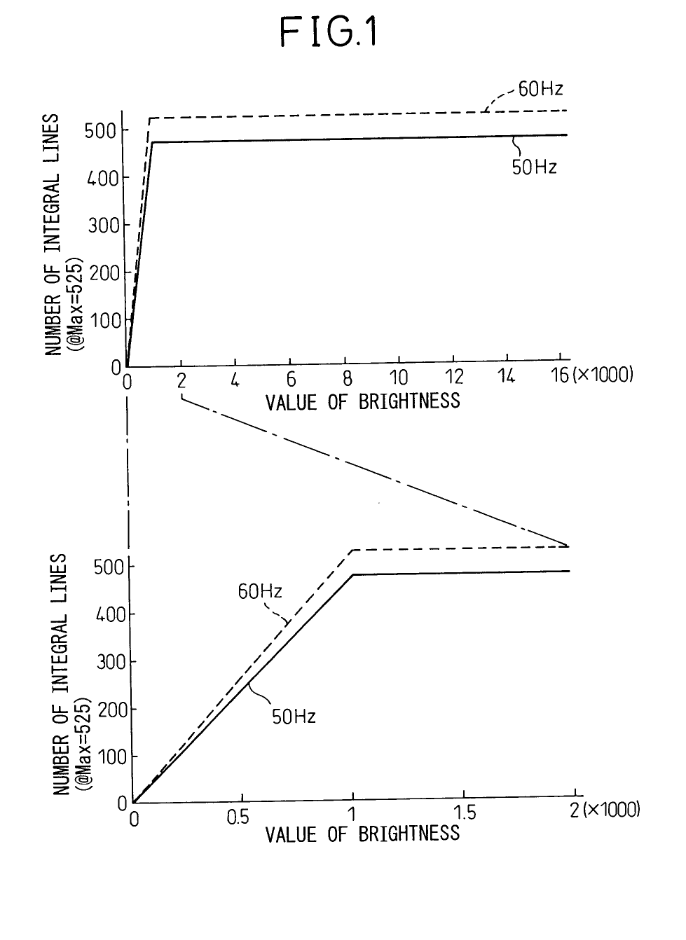

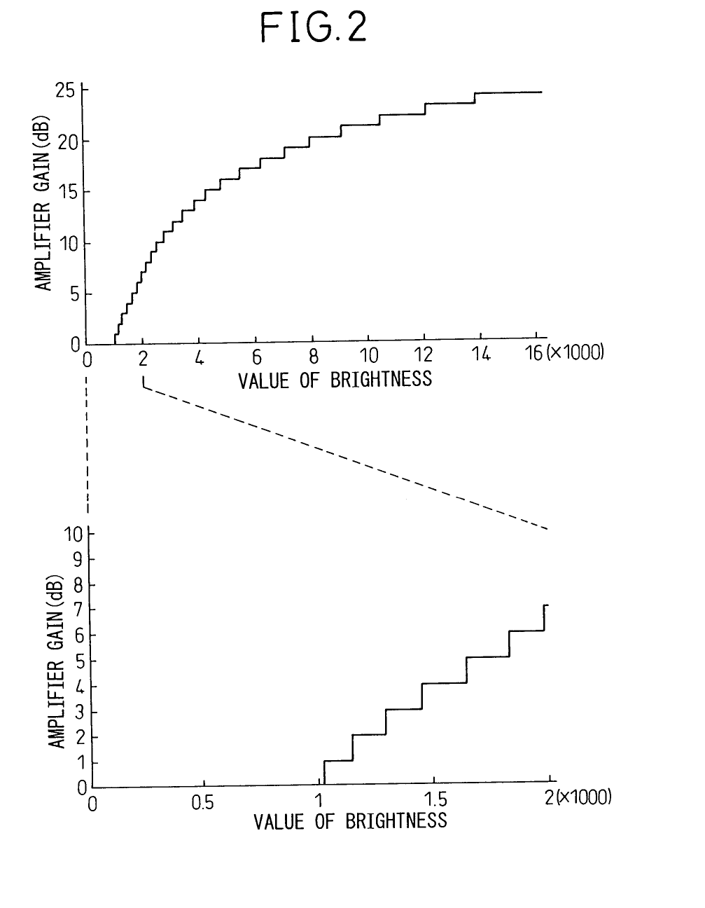

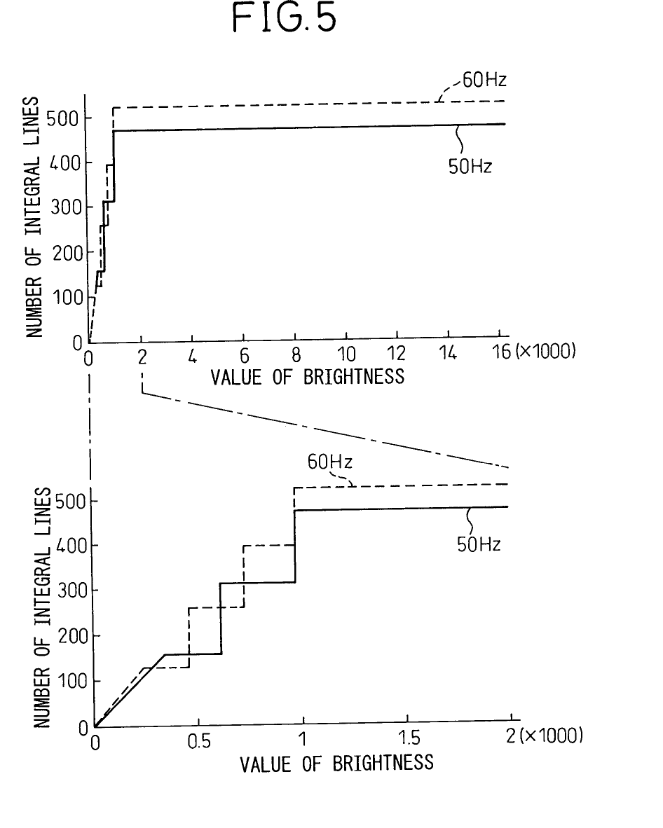

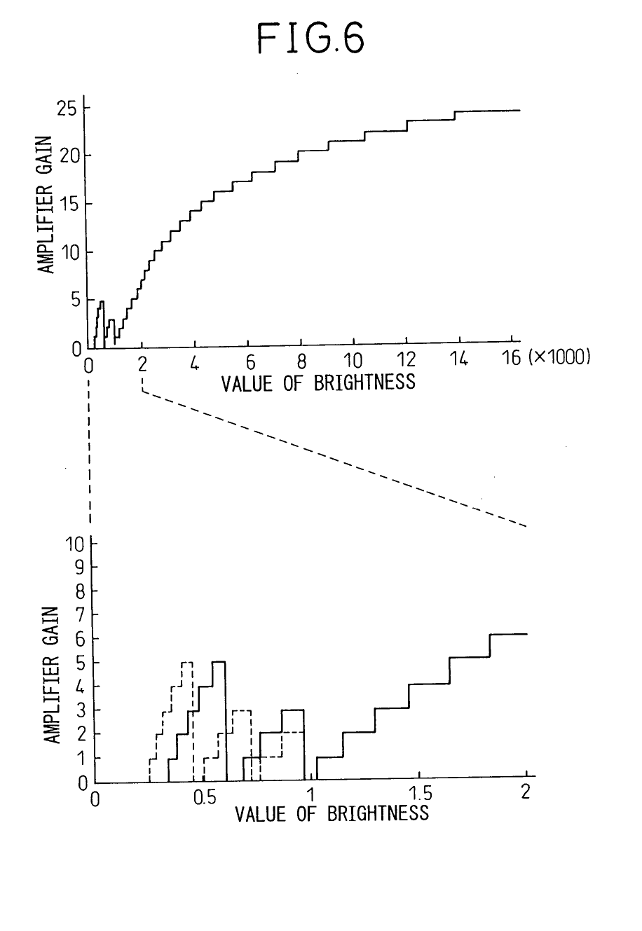

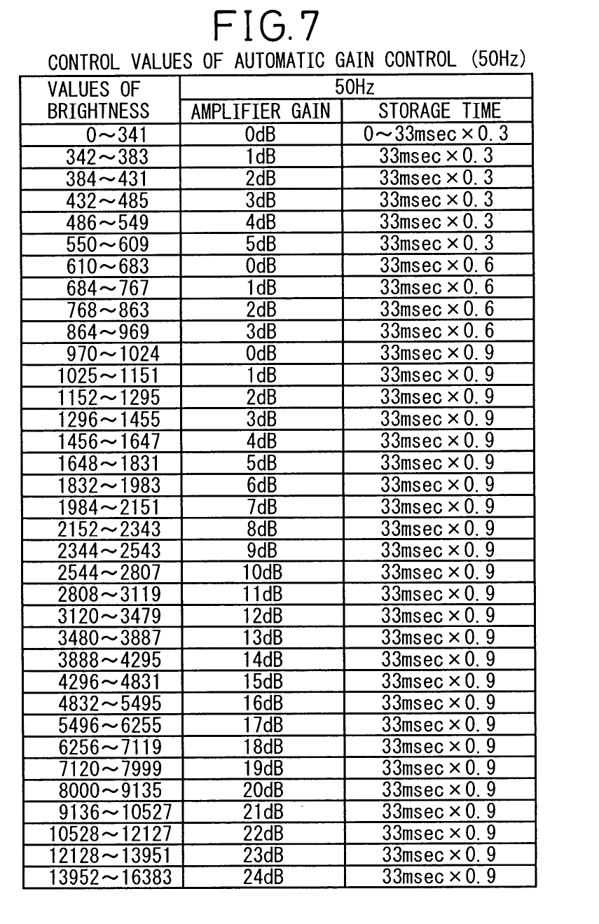

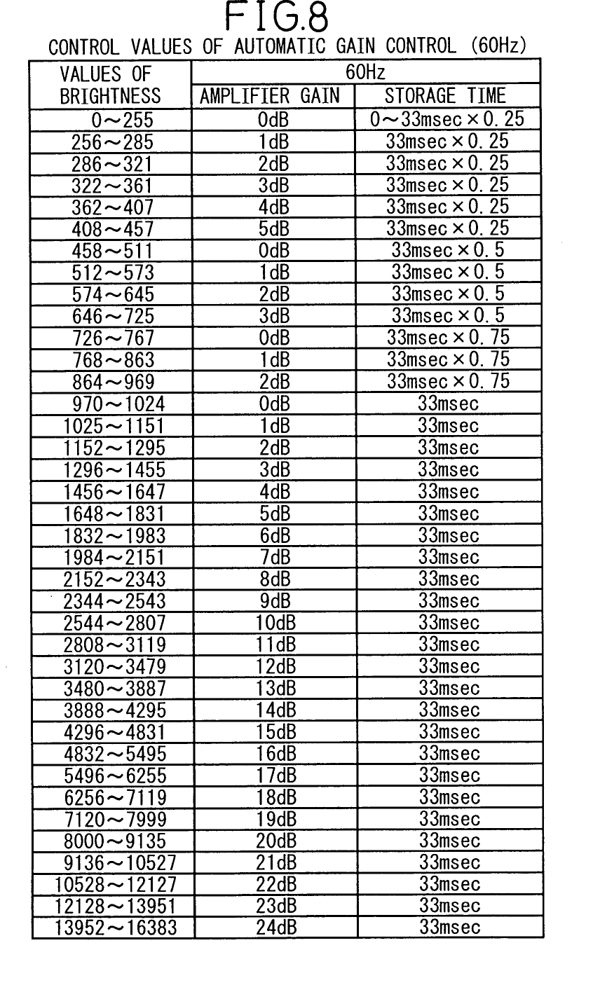

FIG. 5 and FIG. 6 are diagrams illustrating the automatic gain control in the present embodiment, corresponding to FIG. 1 and FIG. 2, respectively, wherein the frame frequency f is 30 Hz. FIG. 5 shows the change in the number of integral lines during the automatic gain control in the present embodiment and FIG. 6 shows the change in amplifier gain during the automatic gain control in the present embodiment. FIG. 7 shows the amplifier gains and the control values of the storage time when a fluorescent lamp is lit by a power source with a frequency of 50 Hz (light emission period is 100 Hz), and FIG. 8 shows the amplifier gains and the control values of the storage time when a fluorescent lamp is lit by a power source with a frequency of 60 Hz (light emission period is 120 Hz).

In the present embodiment, even in the 341 to 2000 range of the value of brightness, the number of integral lines (storage time) is varied step by step, and the amplifier gains are also varied so that the total sensitivity varies smoothly in accordance with the value of brightness, as is obvious from FIG. 5 and FIG. 6. When the light emission period is 120 Hz, the storage time varies step by step as 1/120 sec, 2/120 sec, 3/120 sec, 4/120, and when the light emission period is 100 Hz, the storage time varies step by step as 1/100 sec, 2/100 sec, 3/100 sec. When the storage time varies step by step, the integral time varies by 6 dB at most, therefore, the amplifier gains are adjusted in the meantime.

The brightness/illumination flicker detection section 43 of the processor 41 detects the brightness and the illumination flicker of a light image incident on a pixel in the manner described below. The control section 42 determines the number of integral lines (storage time) and the amplifier gain from the table in FIG. 7 and FIG. 8 according to the detected brightness and illumination flicker, outputs data to direct the number of integral lines (storage time) to the vertical scanning shift register/reset control circuit 4, and outputs data to direct the amplifier gain to the D/A converter 44. For example, when the illumination flicker is 50 Hz and the value of brightness is 500, the storage time is set to 10 ms (160 lines) and the amplifier gain is set to 4 db in accordance with the table in FIG. 7.

The detection of the illumination flicker in the brightness/illumination flicker detection section 43 in the embodiments follows the method disclosed in the above-mentioned Japanese Unexamined Patent Publication (Kokai) No. 2002-330350. This method is briefly described below.

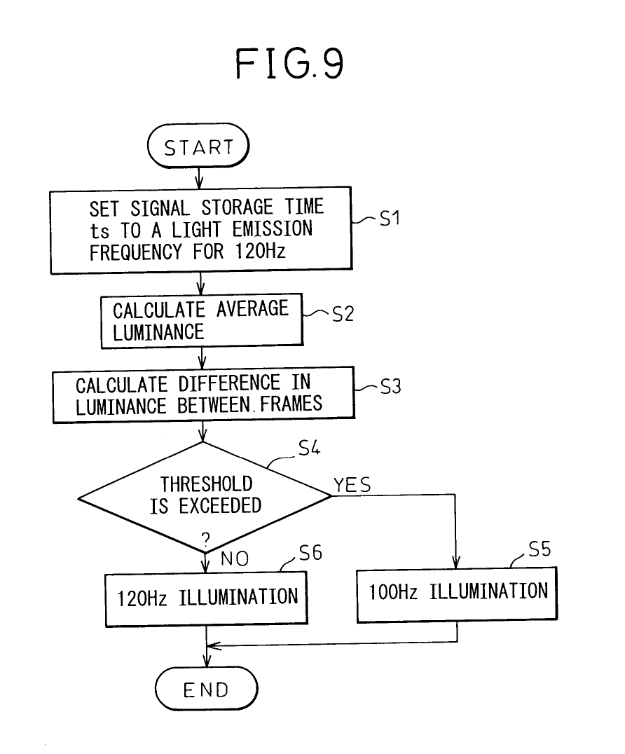

FIG. 9 is a flow chart for detecting illumination flicker. First, the signal storage time of the CMOS image sensor is set to a signal storage time ts at which no flicker noise is caused by the illumination by a fluorescent lamp whose light emission frequency is 120 Hz (step S1). When a light emission period of the fluorescent lamp is 1/120 sec, the luminance variations in a frame due to the flicker noise are 1/120 sec and periodic. Therefore, 1/120, 2/120, 3/120, and 4/120 sec, which are integer multiples of the period, and less than the 1/30 sec frame period of the CMOS image sensor, are the values which the signal storage time can take without causing flicker noise by the illumination of the fluorescent lamp lit at a light emission frequency of 120 Hz.

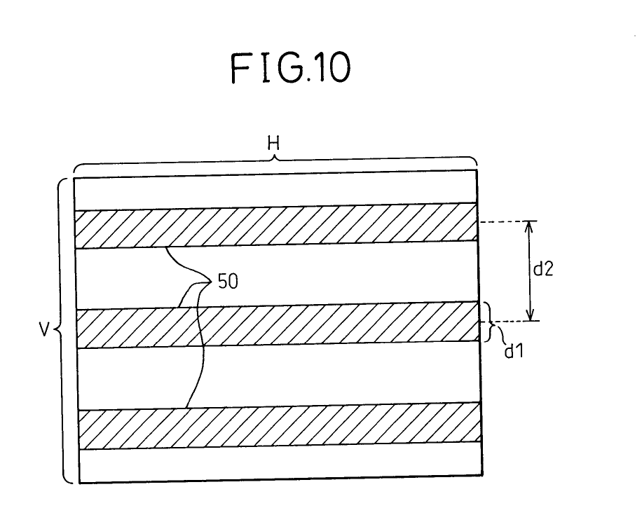

Next, the average luminance of the image data is detected for each frame in a fixed average luminance detection area denoted by reference number 50 on the image surface shown in FIG. 10 (step S2). In FIG. 10, average luminance detection areas 50, shown by slash lines, are shown at three positions at almost equal intervals corresponding to d2 horizontal selection lines. The average luminance detection area 50 is composed of plural pixels connected to a fixed number of adjacent horizontal selection lines. In addition, the number d1 of horizontal selection lines in each average luminance detection area 50 must be adjusted to a number that is not an integer multiple of the period of the luminance variations caused by the flicker noise.

Moreover, it is desirable that the average luminance detection area 50 is provided at one to three positions in a frame at intervals of 3/10 times the width V corresponding to the total horizontal selection lines.

Next, the difference in the average luminance between each frame (for example, between the frame in question and the immediately preceding frame) is calculated (step S3). Then whether the difference in the average luminance exceeds a fixed threshold is judged (step S4). If the difference in the average luminance exceeds the threshold, it is judged that the light emission frequency of the fluorescent lamp is 100 Hz because the luminance differs from frame to frame (step S5). If not, it is judged to be 120 Hz.

The illumination flicker can be judged in the manner described above.

In addition to the detection method of the illumination flicker described above, it is possible to detect illumination flicker by, for example, providing a light receiving device that receives light in proportion to incident light in part of a solid-state image sensor and by detecting the change in amount of light received.

In accordance with the present invention, it is possible to realize a solid-state image sensor that can perform sensitivity adjustment in a wide range without causing flicker or stripes due to the illumination by a fluorescent lamp, as described above.

We claim:

1. A solid-state image sensor, comprising: plural pixels arrayed in a matrix and storing charges in proportion to amount of incident light; and a gain variable amplifier amplifying pixel signals sequentially read from the plural pixels at a fixed cycle time, an amplification factor of which can be varied, and being able to set a storage time during which the plural pixels store charges to an arbitrary value in a time range narrower than a period of the fixed cycle time, wherein the sensor comprises: a brightness/illumination flicker detection section detecting brightness and illumination flicker of an incident light image; and a control section varying the amplification factor of the gain variable amplifier in accordance with the detected brightness and a set value of the storage time as well as varying the storage time step by step to either of plural flicker-less times at which the illumination flicker is not caused in accordance with the detected brightness and the illumination flicker.

2. The solid-state image sensor, as set forth in claim 1, wherein the control section sets the storage time to n/100 sec (n is a positive integer) when the illumination flicker detected by the brightness/illumination flicker detection section has a light emission period corresponding to the case where a fluorescent lamp is lit at 50 Hz.

3. The solid-state image sensor, as set forth in claim 1, wherein the control section sets the storage time to n/120 sec (n is a positive integer) when the illumination flicker detected by the brightness/illumination flicker detection section has a light emission period corresponding to the case where a fluorescent lamp is lit at 60 Hz.

4. The solid-state image sensor, as set forth in claim 1, wherein the brightness/illumination flicker detection section detects average luminance of the pixel signal for each frame in fixed average luminance detection areas assigned in a frame, calculates a difference in the average luminance between frames, and judges whether the illumination flicker is caused by a fluorescent lamp lit at 50 Hz or 60 Hz from the calculated difference in the average luminance.
